(19) United States
(12) Patent Application Publication
(10) Pub. No.: US 2024/0224503 A1
(43) Pub. Date: Jul. 4, 2024

(54) SEMICONDUCTOR DEVICES

(71) Applicant: Samsung Electronics Co., Ltd., Suwon-si (KR)

(72) Inventors: Cheoljin Cho, Suwon-si (KR); Yukyung Shin, Suwon-si (KR); Changhwa Jung, Suwon-si (KR); Jieun Lee, Suwon-si (KR); Jayun Choi, Suwon-si (KR)

(21) Appl. No.: 18/542,627

(22) Filed: Dec. 16, 2023

(30) Foreign Application Priority Data
Dec. 29, 2022 (KR) 10-2022-0188601

(51) Int. Cl. H10B 12/00

(52) U.S. Cl. CPC H10B 12/315

(57) ABSTRACT

A semiconductor device includes a substrate, a first electrode disposed above the substrate, a multilayer dielectric structure configured to cover the first electrode, and a second electrode configured to cover the multilayer dielectric structure. The multilayer dielectric structure includes a plurality of dielectric films, a first dielectric film of the plurality of dielectric films includes crystalline TiO₂ or crystalline SrTiO₃, and a second dielectric film of the plurality of dielectric films is in contact with the first dielectric film and includes a high-k dielectric film having a tetragonal crystal structure.

### CROSS-REFERENCE TO RELATED APPLICATION(S)

This application claims benefit of priority to Korean Patent Application No. 10-2022-0188601 filed on Dec. 29, 2022, in the Korean Intellectual Property Office, the disclosure of which is incorporated herein by reference in its entirety.

### BACKGROUND

The present disclosure relates to semiconductor devices, and more particularly to capacitor structures of the semiconductor devices.

The size of a capacitor of a semiconductor device has been also refined according to the demand for high integration and miniaturization of the semiconductor device. Accordingly, various studies have been attempted to optimize the structure of a capacitor that can store information in a dynamic random-access memory (DRAM).

### SUMMARY

An aspect of the present disclosure is to provide a semiconductor device having improved electrical characteristics and reliability.

According to an aspect of the present disclosure, a semiconductor device includes: a substrate; a first electrode disposed above the substrate; a multilayer dielectric structure configured to cover the first electrode; and a second electrode configured to cover the multilayer dielectric structure. The multilayer dielectric structure includes a plurality of dielectric films, a first dielectric film of the plurality of dielectric films includes crystalline TiO₂ or crystalline SrTiO₃, and a second dielectric film of the plurality of dielectric films is in contact with the first dielectric film and includes a high-k dielectric film having a tetragonal crystal structure.

According to an aspect of the present disclosure, a semiconductor device includes: a substrate; a plurality of first electrodes disposed on the substrate; a multilayer dielectric structure configured to cover the plurality of first electrodes; and a second electrode configured to cover the multilayer dielectric structure. The multilayer dielectric structure includes a plurality of dielectric films, the plurality of dielectric films include a first dielectric film and a second dielectric film formed of different materials, and a crystalline reinforced dielectric film having at least one surface in contact with the first dielectric film, and the first dielectric film includes hafnium oxide (HfO₂) or zirconium oxide (ZrO₂), and the crystalline reinforced dielectric film includes crystalline TiO₂ or crystalline SrTiO₃.

According to an aspect of the present disclosure, a semiconductor device includes: a device isolation layer configured to define active regions on a substrate; gate electrodes intersecting the active regions and extending into the device isolation layer; first impurity regions and second impurity regions disposed within the active regions on opposite sides of the gate electrodes; bit lines disposed at a higher level than the gate electrodes and connected to the first impurity regions; conductive patterns disposed on side surfaces of the bit lines and connected to the second impurity regions; a plurality of first electrodes extending vertically on the conductive patterns and connected to each of the conductive patterns; at least one support layer spaced apart from an upper surface of the substrate in a vertical direction, extending in a direction parallel to the upper surface of the substrate, and contacting with a side surface of each of adjacent first electrodes among the plurality of first electrodes; a multilayer dielectric structure configured to cover the plurality of first electrodes and the support layer; and a second electrode configured to cover the multilayer dielectric structure. The multilayer dielectric structure includes a first dielectric film and a second dielectric film formed of different materials, and a crystalline reinforced dielectric film having at least one surface in contact with the first dielectric film, and the first dielectric film includes hafnium oxide (HfO₂) or zirconium oxide (ZrO₂), and the crystalline reinforced dielectric film includes crystalline TiO₂ or crystalline SrTiO₃.

High electrostatic capacity of a capacitor may be secured by introducing a crystalline reinforced dielectric film, which is crystalline TiO₂ or crystalline SrTiO₃, into a multilayer dielectric structure constituting the capacitor, and improving crystallinity of a high-k dielectric film (specifically, ZrO₂ or HfO₂ having a tetragonal crystal structure) in contact with the crystalline reinforced dielectric film.

Advantages and effects of the present application are not limited to the foregoing content and may be more easily understood in the process of describing a specific example embodiment of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a top plan view illustrating a semiconductor device according to an example embodiment of the present disclosure;

FIG. 2 is a cross-sectional view of the semiconductor device of FIG. 1 taken along line I-I′ and line II-II′ according to example embodiments;

FIG. 3A is a partially enlarged view illustrating part “A” (a capacitor structure) of the semiconductor device of FIG. 2 according to example embodiments, and FIG. 3B is a cross-sectional view of the capacitor structure of FIG. 3A taken along line III-III′ according to example embodiments;

FIG. 4 is a partially enlarged view illustrating part “B” of the capacitor structure of FIG. 3A according to example embodiments;

FIG. 5 is a graph illustrating an effect of improving electrostatic capacity of a capacitor structure according to an example embodiment of the present disclosure;

FIG. 6 is a graph illustrating an effect of improving electrostatic capacity according to the arrangement of an insertion layer in a capacitor structure according to example embodiments of the present disclosure;

FIGS. 7A to 7D are cross-sectional views illustrating various examples of a capacitor structure that may be adopted in a semiconductor device according to an example embodiment of the present disclosure;

FIG. 8 is a top plan view illustrating a semiconductor device according to an example embodiment of the present disclosure;

FIG. 9 is a top plan view illustrating a semiconductor device according to an example embodiment of the present disclosure; and

FIG. 10 is cross-sectional views of the semiconductor device of FIG. 9 taken along line IV-IV′ and line V-V according to example embodiments.

### DETAILED DESCRIPTION

Hereinafter, example embodiments of the present disclosure will be described with reference to the accompanying drawings.

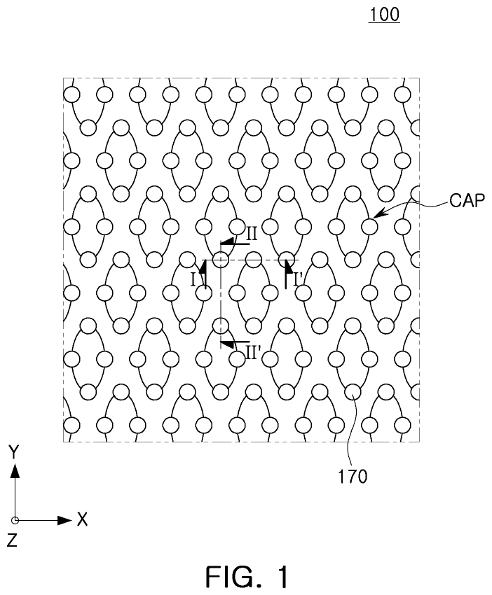

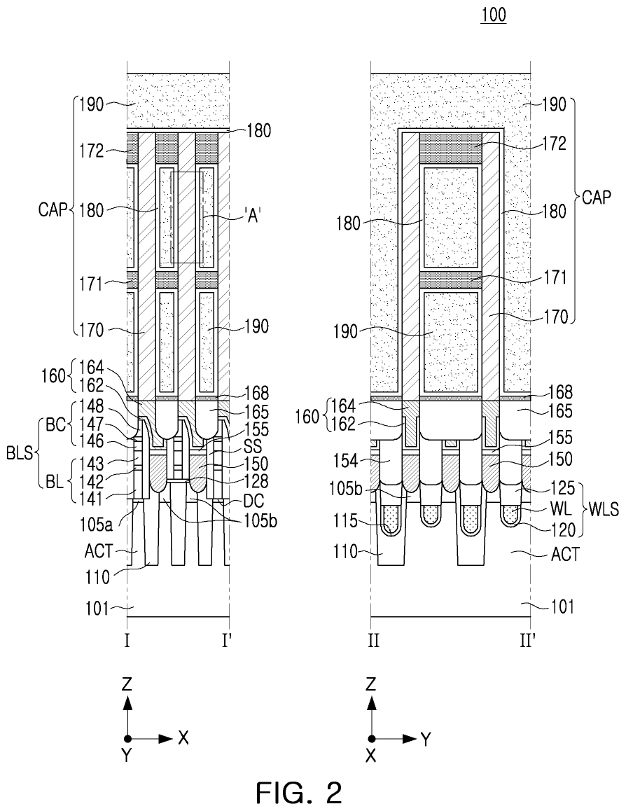

FIG. 1 is a top plan view illustrating a semiconductor device according to an example embodiment of the present disclosure, and FIG. 2 is a cross-sectional view of the semiconductor device of FIG. 1 taken along line I-I′ and line II-II′ according to example embodiments.

Referring to FIGS. 1 and 2, a semiconductor device 100 according to an example embodiment of the present disclosure may include a substrate 101 including active regions ACT, a device isolation layer 110 defining the active regions ACT in the substrate 101, a word line structure WLS embedded in the substrate 101, a bit line structure BLS above the substrate 101, and a capacitor structure CAP above the bit line structure BLS.

The semiconductor device 100 may further include a lower conductive pattern 150 on the active region ACT, an upper conductive pattern 160 on the lower conductive pattern 150, and an insulating pattern 165 penetrating through the upper conductive pattern 160. For example, the semiconductor device 100 may include a cell array of a dynamic random access memory (DRAM). The semiconductor device 100 may include a cell array region in which a cell array is disposed and a peripheral circuit region in which peripheral circuits for driving memory cells disposed in the cell array are disposed. The peripheral circuit region may be disposed around the cell array region.

The word line structure WLS includes a word line WL embedded in the substrate 101, and the bit line structure BLS includes a bit line BL extending by intersecting the word line structure WLS on the substrate 101. For example, the bit line BL is connected to a first impurity region 105a of the active region ACT. A second impurity region 105b of the active region ACT may be electrically connected to the capacitor structure CAP on the upper conductive pattern 160 through the lower and upper conductive patterns 150 and 160.

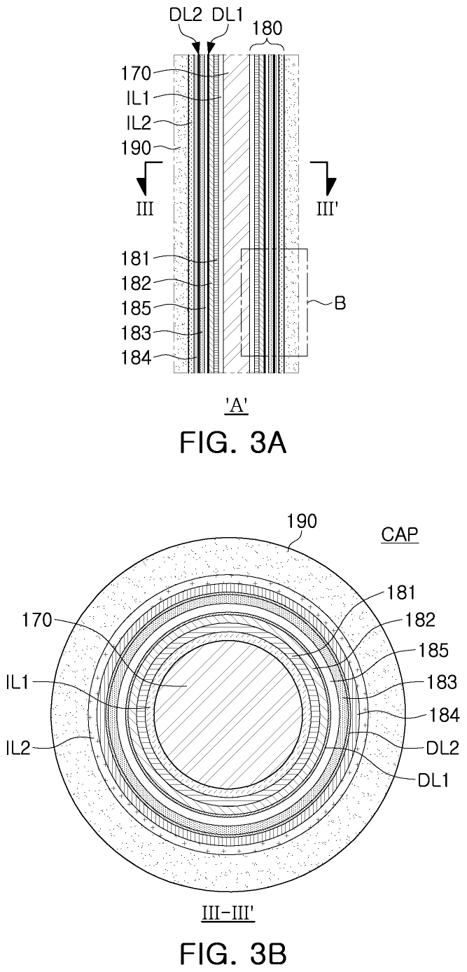

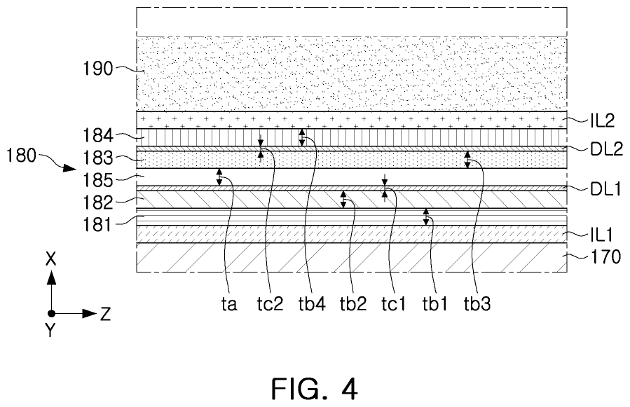

The capacitor structure CAP includes lower electrodes 170 (also referred to as ‘first electrodes’), a dielectric layer (or, a dielectric film) 180 on the lower electrodes 170, and upper electrodes 190 (also referred to as ‘second electrodes’) on the dielectric layer 180. The structures of the capacitor structure CAP and the dielectric layer 180 introduced therein will be described below with reference to FIGS. 3A, 3B, and 4. Herein, for convenience of description, the terms of the “film” and the “layer” may be used interchangeably.

The substrate 101 may be formed of or include a semiconductor material, for example, a Group IV semiconductor, a Group III-V compound semiconductor, or a Group II-VI compound semiconductor. For example, the Group IV semiconductor may include silicon, germanium, or silicon-germanium. The substrate 101 may further include impurities. The substrate 101 may be a silicon substrate, a silicon-on-insulator (SOI) substrate, a germanium substrate, a germanium-on insulator (GOI) substrate, a silicon-germanium substrate, or a substrate including an epitaxial layer.

The active regions ACT may be defined in the substrate 101 by the device isolation layer 110. The active region ACT may have a bar shape and may be disposed in the substrate 101 in an island shape extending in one direction. The one direction may be a direction inclined with respect to an extending direction of the word lines WL and the bit lines BL. The active regions ACT may be arranged in parallel with each other, but an end of one active region ACT may be arranged adjacent to a center of another active region ACT disposed adjacent thereto.

The active region ACT may have the first and second impurity regions 105a and 105b having a predetermined depth from an upper surface of the substrate 101. The first and second impurity regions 105a and 105b may be spaced apart from each other. The first and second impurity regions 105a and 105b may be provided as a source/drain region of a transistor configured by the word line WL. The source region and the drain region may be formed by the first and second impurity regions 105a and 105b by doping with impurities of the same conductivity type or an ion injection. The impurities may include impurities having a conductivity type (e.g., N-type) opposite to a conductivity type (e.g., P-type) of the substrate 101. Depending on a circuit configuration of the transistor, first and second impurity regions of different conductivity types (e.g., P-type) may be included. In some example embodiments, depths of the first and second impurity regions 105a and 105b in the source region and the drain region may be different from each other.

The device isolation layer 110 may be formed by a shallow trench isolation (STI) process. The device isolation layer 110 may surround the active regions ACT and electrically separate the active regions ACT from each other. The device isolation layer 110 may be formed of or include an insulating material, for example, silicon oxide, silicon nitride, or combinations thereof. The device isolation layer 110 may include a plurality of regions having different bottom depths depending on a width of a trench on which the substrate 101 is etched.

The word line structures WLS may be disposed in gate trenches 115 extending in the substrate 101. Each of the word line structures WLS may include a gate dielectric layer 120, a word line WL, and a gate capping layer 125. In the present specification, ‘a gate’ may be referred to as a structure including the gate dielectric layer 120 and the word line WL, the word line WL may be referred to as a ‘gate electrode,’ and the word line structure WLS may be referred to as a ‘gate structure.’

The word line WL may be disposed to extend in a first direction (X-direction) across the active region ACT. For example, a pair of word lines WL adjacent to each other may be disposed to intersect one active region ACT. The word line WL may constitute a gate of a buried channel array transistor (BCAT), but the present disclosure is not limited thereto. In some example embodiments, the word line WL may have a shape disposed on an upper portion of the substrate 101. The word line WL may be disposed below the gate trench 115 to have a predetermined thickness. An upper surface of the word line WL may be disposed on a lower level than the upper surface of the substrate 101. In the present specification, for the term “level” used therein, high and low levels may be defined based on a substantially flat upper surface of the substrate 101. Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

The word line WL may be formed of or include at least one conductive material, such as polycrystalline silicon (Si), titanium (Ti), titanium nitride (TiN), tantalum (Ta), tantalum nitride (TaN), tungsten (W), tungsten nitride (WN), and aluminum (Al). For example, the word line WL may include a lower pattern and an upper pattern formed of different materials, the lower pattern may include at least one of tungsten (W), titanium (Ti), tantalum (Ta), tungsten nitride (WN), titanium nitride (TiN), and tantalum nitride (TaN), and the upper pattern may be a semiconductor pattern including polysilicon doped with P-type or N-type impurities.

The gate dielectric layer 120 may be disposed on a bottom surface and internal surfaces of the gate trench 115. The gate dielectric layer 120 may conformally cover an internal sidewall of the gate trench 115. The gate dielectric layer 120 may be formed of or include at least one of silicon oxide, silicon nitride, and silicon oxynitride. The gate dielectric layer 120 may be, for example, a silicon oxide film or an insulating film having a high dielectric constant. In exemplary embodiments, the gate dielectric layer 120 may be a layer formed by oxidizing the active region (ACT) or a layer formed by deposition.

The gate capping layer 125 may be disposed to fill the gate trench 115 at an upper portion of the word line WL. An upper surface of the gate capping layer 125 may be disposed on substantially the same level as the upper surface of the substrate 101. The gate capping layer 125 may be formed of an insulating material such as silicon nitride.

The bit line structure BLS may extend in one direction perpendicular to the word line WL, for example, in a second direction (Y-direction). The bit line structure BLS adopted in the example embodiment of the present disclosure may include a bit line BL and a bit line capping pattern BC on the bit line BL.

The bit line BL may include a first conductive pattern 141, a second conductive pattern 142, and a third conductive pattern 143 which are sequentially stacked. The bit line capping pattern BC may be disposed on the third conductive pattern 143. A buffer insulating layer 128 may be disposed between the first conductive pattern 141 and the substrate 101, and a portion of the first conductive pattern 141 (hereinafter referred to as a bit line contact pattern DC) may be in contact with the first impurity region 105a of the active region ACT. It will be understood that when an element is referred to as being “connected” or “coupled” to another element, it can be directly connected or coupled to the other element or intervening elements may be present. The term “contact” or “in contact with” as used herein refers to a direct connection, e.g., touching. The bit line BL may be electrically connected to the first impurity region 105a through the bit line contact pattern DC. A lower surface of the bit line contact pattern DC may be disposed on a lower level than the upper surface of the substrate 101 and may be disposed on a higher level than the upper surface of the word line WL. For example, the bit line BL may be disposed at a higher level than the word line WL. In some example embodiments, the bit line contact pattern DC may be formed in the substrate 101 and disposed locally inside a bit line contact hole exposing the first impurity region 105a.

The first conductive pattern 141 may include a semiconductor material such as polycrystalline silicon. The first conductive pattern 141 may be in contact with the first impurity region 105a. The second conductive pattern 142 may include a metal-semiconductor compound. The metal-semiconductor compound may be, for example, a layer obtained by converting a portion of the first conductive pattern 141 into silicide. For example, the metal-semiconductor compound may include cobalt silicide (CoSi), titanium silicide (TiSi), nickel silicide (NiSi), tungsten silicide (WSi), or other metal silicide. The third conductive pattern 143 may include a metal material such as titanium (Ti), tantalum (Ta), tungsten (W), and aluminum (Al). The number of conductive patterns constituting the bit line BL, the type of material, and/or the stacking order may be variously changed according to example embodiments.

The bit line capping pattern BC may include a first capping pattern 146, a second capping pattern 147, and a third capping pattern 148 which are sequentially stacked on the third conductive pattern 143. Each of the first to third capping patterns 146, 147 and 148 may include an insulating material, for example, a silicon nitride film. The first to third capping patterns 146, 147 and 148 may be formed of different materials, and even if the first to third capping patterns 146, 147 and 148 are formed of the same material, boundaries therebetween may be distinguished due to differences in physical properties thereof. A thickness of the second capping pattern 147 may be less than a thickness of the first capping pattern 146 and a thickness of the third capping pattern 148, respectively. The number of capping patterns constituting the bit line capping pattern BC and/or the type of material may be variously changed according to example embodiments.

A spacer structures SS may be disposed on opposite sidewalls of each of the bit line structures BLS and may extend in the second direction (Y-direction). The spacer structures SS may be disposed between the bit line structure BLS and the lower conductive pattern 150. The spacer structures SS may be disposed to extend along sidewalls of the bit line BL and sidewalls of the bit line capping pattern BC. A pair of spacer structures SS disposed on opposite sides of one bit line structure BLS may have an asymmetrical shape based on the bit line structure BLS. Each of the spacer structures SS may include a plurality of spacer layers, and in some example embodiments, each of the spacer structures SS may further include an air spacer.

The lower conductive pattern 150 may be connected to one region of the active region ACT, for example, the second impurity region 105b. The lower conductive pattern 150 may be disposed between the bit lines BL and between the word lines WL. The lower conductive pattern 150 may penetrate through the buffer insulating layer 128 and may be connected to the second impurity region 105b of the active region ACT. The lower conductive pattern 150 may be in contact with the second impurity region 105b. A lower surface of the lower conductive pattern 150 may be disposed on a lower level than the upper surface of the substrate 101, and may be disposed on a higher level than the lower surface of the bit line contact pattern DC. The lower conductive pattern 150 may be insulated from the bit line contact pattern DC by the spacer structure SS. The lower conductive pattern 150 may be formed of a conductive material, and may include at least one of polycrystalline silicon (Si), titanium (Ti), titanium nitride (TiN), tantalum (Ta), tantalum nitride (TaN), tungsten (W), tungsten nitride (W), and aluminum (Al). In example embodiments, the lower conductive pattern 150 may include a plurality of layers.

A metal semiconductor compound layer 155 may be disposed between the lower conductive pattern 150 and the upper conductive pattern 160. The metal semiconductor compound layer 155 may be a layer in which a portion of the lower conductive pattern 150 is converted into silicide, for example, when the lower conductive pattern 150 includes a semiconductor material. The metal semiconductor compound layer 155 may include, for example, cobalt silicide (CoSi), titanium silicide (TiSi), nickel silicide (NiSi), tungsten silicide (WSi), or other metal silicide. According to example embodiments, the metal semiconductor compound layer 155 may be omitted.

The upper conductive pattern 160 may be disposed on the lower conductive pattern 150. The upper conductive pattern 160 may extend between the spacer structures SS to cover an upper surface of the metal semiconductor compound layer 155. The upper conductive pattern 160 may include a barrier layer 162 and a conductive layer 164. The barrier layer 162 may cover a lower surface and side surfaces of the conductive layer 164. The barrier layer 162 may include metal nitride, for example, at least one of titanium nitride (TiN), tantalum nitride (TaN), and tungsten nitride (WN). The conductive layer 164 may include a conductive material, for example, at least one of polycrystalline silicon (Si), titanium (Ti), tantalum (Ta), tungsten (W), ruthenium (Ru), copper (Cu), molybdenum (Mo), platinum (Pt), nickel (Ni), cobalt (Co), aluminum (Al), titanium nitride (TiN), tantalum nitride (TaN), and tungsten nitride (WN).

The insulating patterns 165 may be disposed to penetrate through the upper conductive pattern 160. A plurality of upper conductive patterns 160 may be separated by the insulating patterns 165. The insulating patterns 165 may include an insulating material, for example, at least one of silicon oxide, silicon nitride, and silicon oxynitride.

An etch stop layer 168 may cover the insulating patterns 165 between the lower electrodes 170. The etch stop layer 168 may be in contact with lower regions of side surfaces of the lower electrodes 170. The etch stop layer 168 may be disposed below support layers 171 and 172. An upper surface of the etch stop layer 168 may include a portion in contact with the dielectric layer 180. The etch stop layer 168 may include, for example, at least one of silicon nitride and silicon oxynitride.

The lower electrodes 170 may be disposed on the upper conductive patterns 160. The lower electrodes 170 may penetrate through the etch stop layer 168 and may be in contact with the upper conductive patterns 160. The lower electrodes 170 may have a cylindrical shape, but the present disclosure is not limited thereto. In other example embodiments, the lower electrodes 170 may have a hollow cylinder or a cup shape or a planar shape.

At least one of the support layers 171 and 172 supporting the lower electrodes 170 may be provided between adjacent lower electrodes 170. For example, between the adjacent lower electrodes 170, a first support layer 171 and a second support layer 172 in contact with the lower electrodes 170 may be provided. Each of the lower electrodes 170 may include at least one of polycrystalline silicon (Si), titanium (Ti), titanium nitride (TiN), tantalum (Ta), tantalum nitride (TaN), tungsten (W), tungsten nitride (WN), and aluminum (Al).

In example embodiments, additional three or more support layers spaced apart from each other in a direction (Z direction) may be disposed between the dielectric layer 180 and the etch stop layer 168. For example, the additional three or more support layers may support the lower electrodes 170 between the adjacent lower electrodes 170.

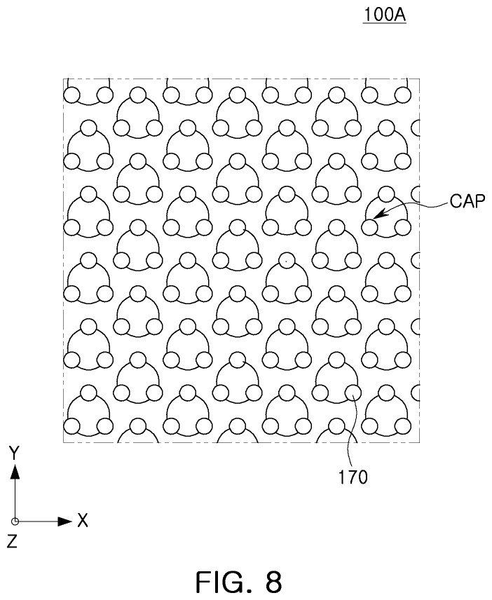

Referring to FIG. 1, the lower electrodes 170 may have a regular arrangement in a top plan view viewed from above. The lower electrodes 170 may be spaced apart from each other by a predetermined distance in the first direction (X-direction), and may be disposed in a zigzag manner in the second direction (Y-direction). A through-hole pattern may be disposed between a plurality of adjacent lower electrodes 170. As illustrated in FIG. 1, one through-hole pattern may be disposed between four adjacent lower electrodes 170. However, the arrangement of the lower electrodes 170 is not limited thereto, and may have another arrangement (see FIG. 8).

The first and second support layers 171 and 172 may be disposed to be spaced apart from the substrate 101 in a direction (Z direction) perpendicular to the upper surface of the substrate 101. The first and second support layers 171 and 172 may be in contact with the lower electrodes 170 and may extend in a direction parallel to the upper surface of the substrate 101. Each of the first and second support layers 171 and 172 may include portions in contact with the lower electrodes 170 and the dielectric layer 180. The second support layer 172 may have a thickness thicker than that of the first support layer 171, but the present disclosure is not limited thereto. The first and second support layers 171 and 172 may be layers supporting the lower electrodes 170 having a high aspect ratio. Each of the first and second support layers 171 and 172 may include, for example, at least one of silicon nitride and silicon oxynitride, or an insulating material similar thereto. The number, thickness, and/or arrangement relationship of the first and second support layers 171 and 172 is not limited to those illustrated, and may be variously changed in some example embodiments.

The dielectric layer 180 may cover the lower electrodes 170 on the surfaces of the lower electrodes 170. The dielectric layer 180 may be disposed between the lower electrodes 170 and the upper electrode 190. The dielectric layer 180 may cover upper and lower surfaces of the first and second support layers 171 and 172. The dielectric layer 180 may cover an upper surface of the etch stop layer 168.

The dielectric layer 180 adopted in an example embodiment of the present disclosure may have a multilayer dielectric structure including a plurality of dielectric layers (see FIGS. 3A, 3B and 4).

FIG. 3A is a partially enlarged view illustrating part “A” (a capacitor structure) of the semiconductor device of FIG. 2 according to example embodiments, and FIG. 3B is a cross-sectional view of the capacitor structure of FIG. 3A taken along line III-III′ according to example embodiments. FIG. 4 is a partially enlarged view illustrating part “B” of the capacitor structure of FIG. 3A according to example embodiments.

Referring to FIGS. 3A, 3B and 4, the dielectric layer 180 having the multilayer dielectric structure includes a plurality of dielectric layers 181, 182, 183, 184 and 185. In an example embodiment of the present disclosure, the plurality of dielectric layers may include a first dielectric film 181, a second dielectric film 182, a crystalline reinforced dielectric film 185, a third dielectric film 183, and a fourth dielectric film 184, which are sequentially stacked. For example, the dielectric layer 180 may have a thickness of 100 Å or less. In some example embodiments, the thickness of the dielectric layer 180 may range from 30 Å to 80 Å.

The crystalline reinforced dielectric film 185 may be disposed between the second and third dielectric films 182 and 183 to improve the crystallinity of the adjacent second and third dielectric films 182 and 183. The crystalline reinforced dielectric film 185 may be provided as a seed layer during a growth process to improve the crystallinity of the third dielectric film 183 that is subsequently grown. In a subsequent heat treatment process, the crystalline reinforced dielectric film 185 may further improve the crystallinity of the second and third dielectric films 182 and 183 in contact with opposite sides thereof.

In an example embodiment of the present disclosure, the crystalline reinforced dielectric film 185 may be formed of or include crystalline TiO₂ or crystalline SrTiO₃. The crystalline TiO₂ may have a crystal structure of rutile, anatase, or brucite. Specifically, TiO₂ of the rutile or anatase crystal structure may have not only an advantageous lattice constant (a=4.592 Å for rutile crystal, a=3.785 Å for anatase crystal) but also a high dielectric constant (about 80 to 170 for rutile crystal, 40 for anatase crystal). The crystalline SrTiO₃ has a perovskite crystal structure (a=3.905 Å) and may have a high dielectric constant of 100 to 300.

As described above, the crystalline reinforced dielectric film 185 is made up of crystalline structures, but is not limited to 100% crystalline structures, and mainly includes crystalline structures. For example, an amorphous ratio of the crystalline reinforced dielectric film 185 adopted in the example embodiment of the present disclosure may be less than 10%. For example, a thickness ta of the crystalline reinforced dielectric film 185 may be 10 Å to 30 Å.

Furthermore, because the crystalline reinforced dielectric film 185 has a high dielectric constant as described above, it may be introduced as a high-k dielectric film that replaces an existing dielectric film and may thus improve the crystallinity of the adjacent second and third dielectric films 182 and 183 to secure high capacitance.

Dielectric films 181, 182, 183 and 184 among the plurality of dielectric films may include dielectric films of different materials from each other or from the crystalline reinforced dielectric film 185. For example, the dielectric films 181,182,183 and 184 may include or be formed of hafnium oxide, aluminum oxide, yttrium oxide, scandium oxide, and/or lanthanum oxide. For example, each of a thickness tb1 of the dielectric film 181, a thickness tb2 of the dielectric film 182, a thickness tb3 of the dielectric film 183, and a thickness tb4 of the dielectric film 184 may range from 5 Å to 20 Å.

Among the other dielectric films, the third dielectric film 183 may be in contact with the crystalline reinforced dielectric film 185. The third dielectric film 183 may include or be formed of hafnium oxide (HfO₂) or zirconium oxide (ZrO₂). The third dielectric film 183 may have relatively high crystallinity due to the crystalline reinforced dielectric film 185. For example, the third dielectric film 183 may include or be formed of hafnium oxide or zirconium oxide having a tetragonal crystal structure. In some example embodiments, the crystalline reinforced dielectric film 185 may include or be formed of rutile or anatase TiO₂, and the third dielectric film 183 adjacent thereto may include or be formed of zirconium oxide having a tetragonal crystal structure.

The second dielectric film 182 is disposed between the crystalline reinforced dielectric film 185 and a first insertion layer DL1, but because the first insertion layer DL1 is thin, the crystallinity of the second dielectric film 182 may be further improved by the crystalline reinforced dielectric film 185 during a subsequent heat treatment. The second dielectric film 182 may include or be formed of hafnium oxide or zirconium oxide having a tetragonal crystal structure.

As described above, the dielectric film 182 or 183 configured to improve crystallinity may be disposed on at least one of opposite sides of the crystalline reinforced dielectric film 185, and the dielectric film 182 or 183 may include or be formed of hafnium oxide or zirconium oxide, and the crystalline reinforced dielectric film 185 may include or be formed of crystalline TiO₂ or crystalline SrTiO₃.

In some example embodiments, each of the first and third dielectric films 181 and 183 may include or be formed of zirconium oxide, and each of the second and fourth dielectric films 182 and 184 may include or be formed of hafnium oxide. The second and third dielectric films 182 and 183 adjacent to the crystalline reinforced dielectric film 185 may have improved crystallinity due to the crystalline reinforced dielectric film 185. Furthermore, due to the improved crystallinity of the second and third dielectric films 182 and 183, the crystallinity of the first and fourth dielectric films 181 and 184 may be further improved. Furthermore, because the crystalline reinforced dielectric film 185 has a high dielectric constant (e.g., 40 or more), it may contribute to an increase in electrostatic capacity of the capacitor structure CAP.

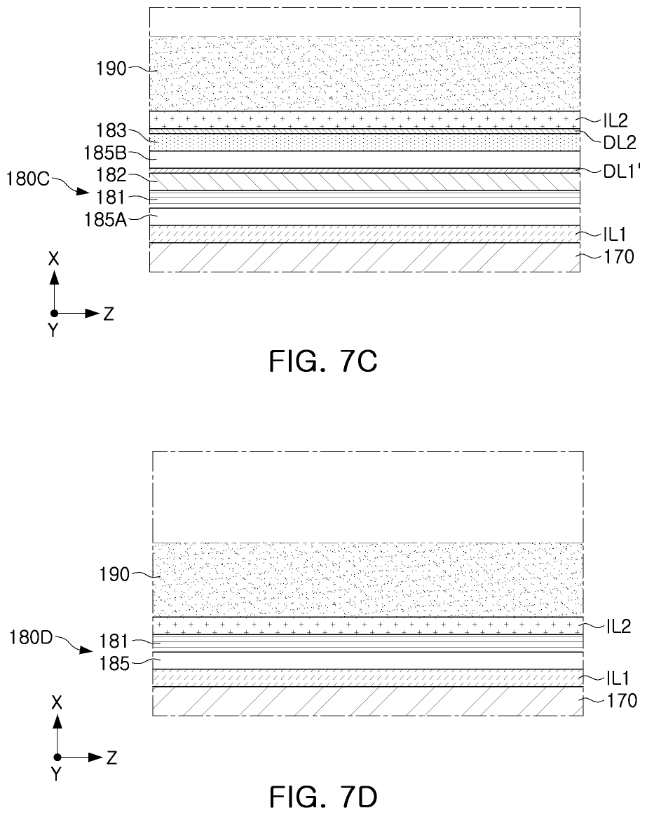

The plurality of dielectric films adopted in the example embodiment of the present disclosure are illustrated as five dielectric films 181,182,183,184 and 185 including a crystalline reinforced dielectric film 185, but the present disclosure is not limited thereto, and in some example embodiments, the plurality of the dielectric films may include the crystalline reinforced dielectric film and at least one dielectric film adjacent thereto. In some example embodiments (see FIG. 7C), the plurality of dielectric films may introduce two or more crystalline reinforced dielectric films.

The dielectric layer 180 adopted in an example embodiment of the present disclosure may further include a first interface layer IL1 disposed between the lower electrodes 170 and the first dielectric film 181, and a second interface layer IL2 between the upper electrode 190 and the fourth dielectric film 184. For example, each of the first interface layer IL1 and the second interface layer IL2 may include or be formed of an oxide or a nitride including at least one element selected from the group consisting of Ta, Sb, Mo, Co, Nb, Cu, Ni, V, and W.

The dielectric layer 180 may further include at least one of the first and second insertion layers DL1 and DL2 disposed between the plurality of dielectric layers. Each of the first and second insertion layers DL1 and DL2 may include or be formed of an oxide or a nitride containing trivalent or pentavalent metal. For example, each of the first and second insertion layers DL1 and DL2 may include or be formed of an oxide or a nitride containing metals selected from the group consisting of Al, Y, La, B, In, V, Ta, and Nb. The adjacent dielectric layers 182, 183 and 184 may be doped with a metal to induce a crystal phase or may suppress a leakage current due to defects.

The dielectric layer 180 adopted in an example embodiment of the present disclosure may further include first and second insertion layers DL1 and DL2 containing metals having different valence. For example, the first insertion layer DL1 disposed between the second dielectric film 182 and the crystalline reinforced dielectric film 185 may include or be formed of an oxide of a trivalent metal (e.g., Al), and the second insertion layer DL2 disposed between the third dielectric film 183 and the fourth dielectric film 184 may include or be formed of an oxide of a pentavalent metal (e.g., Nb). For example, each of a thickness tc1 of the first insertion layer DL1 and a thickness tc2 of the second insertion layer DL2 may range from 0.05 Å to 5 Å. The first and second insertion layers DL1 and DL2 may have different thicknesses (tc1≠tc2). In an example embodiment of the present disclosure, although the number of insertion layers DL1 and DL2 is exemplified as two, various different numbers of insertion layers may be introduced between the plurality of dielectric layers (see FIG. 7B), and one insertion layer DL1′ (see FIG. 7B) may be an oxide or a nitride containing two or more metals having different valences, and the adjacent dielectric films 181 and 182 may be co-doped with metals having different valence.

The upper electrode 190 may cover the plurality of lower electrodes 170, the first and second support layers 171 and 172, and the dielectric layer 180. The upper electrode 190 may fill a space between the plurality of lower electrodes 170 and a space between the first and second support layers 171 and 172. The upper electrode 190 may be in contact with the dielectric layer 180.

As illustrated in FIG. 2, the upper electrode 190 may be formed of a single electrode layer, but the present disclosure is not limited thereto, and in other example embodiments, the upper electrode 190 may include a plurality of electrode layers. The upper electrode 190 may include or be formed of a conductive material. The upper electrode 190 may include or be formed of, for example, at least one of polycrystalline silicon (Si), titanium (Ti), titanium nitride (TiN), tantalum (Ta), tantalum nitride (TaN), tungsten (W), and tungsten nitride (WN).

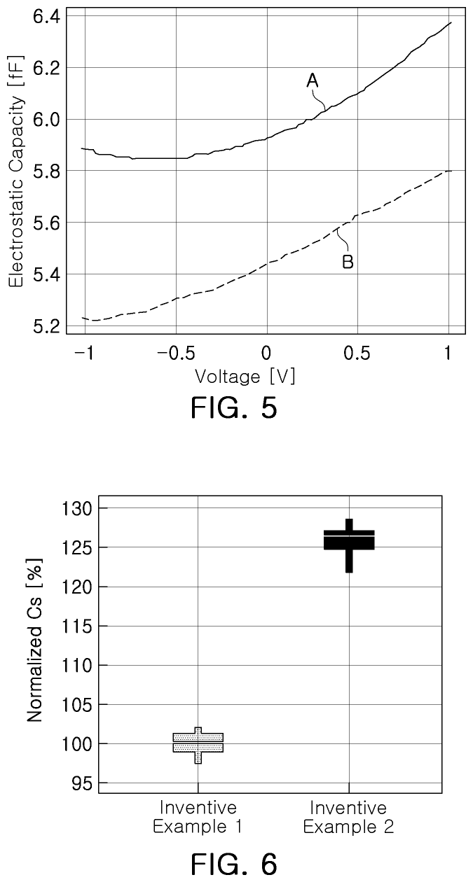

In order to confirm the effect of an introduction of the crystalline reinforced dielectric film, the dielectric layer according to an inventive example of the present disclosure was prepared as follows. After forming TiO₂ as a crystalline reinforced dielectric film, ZrO₂ and HfO₂ were formed thereon twice alternately using atomic layer deposition (ALD) to form a multilayer structure of TiO₂(15 Å)/ZrO₂(10 Å)/HfO₂(8 Å)/ZrO₂(8 Å)/HfO₂(5 Å). In contrast, in Comparative Example B (see FIG. 5), HfO₂ of the same thickness was formed instead of TiO₂, the crystallinity-reinforced dielectric film of previous Inventive Example A, and then, two dielectric constants were compared. As a result, a graph of FIG. 5 illustrates the electrostatic capacity of the dielectric layer according to the Inventive Example and the Comparative Example.

Referring to FIG. 5, the dielectric layer according to Inventive Example A had an electrostatic capacity higher than that of the dielectric layer according to Comparative Example B. It may be seen that the dielectric layer according to Inventive Example A had a significantly improved electrostatic capacity of 15% to 20% with the introduction of the crystalline reinforced dielectric film, which may improve the crystallinity of an adjacent ZrO₂ dielectric film due to the crystalline reinforced dielectric film and improve a dielectric constant thereof, and it may be also seen that because the crystalline reinforced dielectric film of TiO₂ as a rutile phase and/or an anatase phase also had a high dielectric constant, an overall electrostatic capacity was greatly improved.

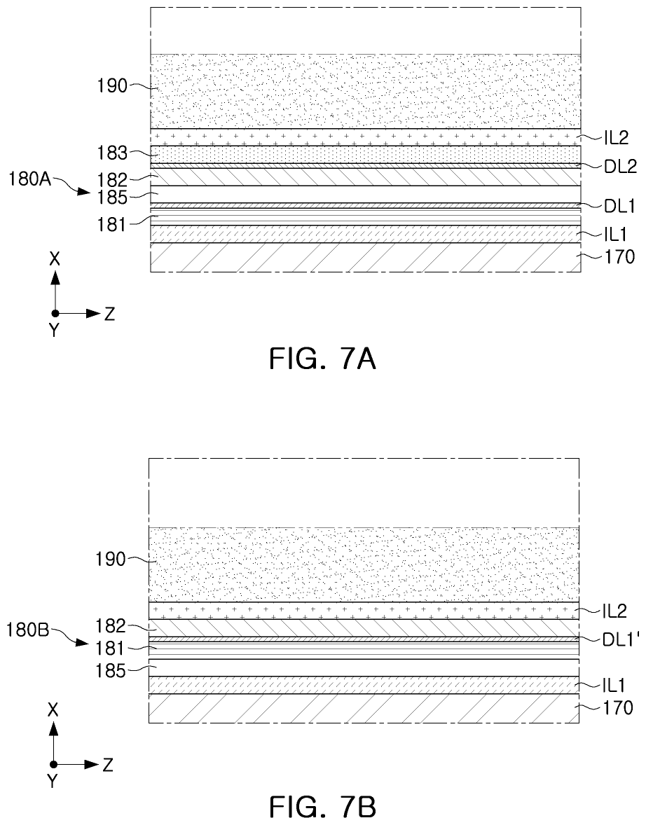

Furthermore, in the previous Inventive Example A, the first and second insertion layers may be additionally formed between TiO₂(15 Å)/ZrO2(10 Å) and between ZrO₂(8 Å)/HfO2(5 Å), respectively. In the instant case, as compared to a case in which each of the first and second insertion layers was formed with an Al-containing oxide doped with Al (+3 valence), and a case in which the first insertion layer was formed with an oxide containing Al doped with Al (+3 valence) and the second insertion layer was formed with an oxide containing Nb doped with Nb (+5 valence), an improvement effect of electrostatic capacity of about 25% or more may be confirmed as illustrated in FIG. 6. In this manner, when the dielectric film is doped with metals of different valences using the insertion layer, more improved crystallinity and leakage current effects may be expected.

FIGS. 7A to 7D are cross-sectional views illustrating various examples of a capacitor structure that may be adopted in a semiconductor device according to an example embodiment of the present disclosure.

Referring to FIG. 7A, a capacitor structure according to an example embodiment of the present disclosure may be understood as being similar to the capacitor structure CAP of the semiconductor device 100 illustrated in FIGS. 1 to 4, except that it has a different number of dielectric films 181, 182, 183 and 185. Furthermore, the components of an example embodiment of the present disclosure may be understood by referring to the description of the capacitor structure CAP and the dielectric layer 180 of the semiconductor device 100 illustrated in FIGS. 1 to 4, unless there is a specific contrary explanation thereof.

Unlike the previous example embodiment, a dielectric layer 180A adopted in an example embodiment of the present disclosure may include the first dielectric film 181, the crystalline reinforced dielectric film 185, the second dielectric film 182, and the third dielectric film 183. The crystalline reinforced dielectric film 185 may include or be formed of crystalline TiO₂ or crystalline SrTiO₃, and may have a dielectric constant of 40 or more. For example, a thickness of the crystalline reinforced dielectric film 185 may range from 10 Å to 30 Å. For example, the first and second dielectric films 181 and 182 adjacent to the crystalline reinforced dielectric film 185 may include or be formed of hafnium oxide or zirconium oxide and may have a tetragonal crystal structure. In some example embodiments, the crystalline reinforced dielectric film 185 includes rutile or anatase TiO₂, and at least the second dielectric film 182 adjacent thereto may include or be formed of zirconium oxide of a tetragonal crystal structure.

The dielectric layer 180A adopted in an example embodiment of the present disclosure may include further first and second insertion layers DL1 and DL2 containing metals having different valences, similarly to the previous example embodiment. The dielectric layer 180A may include a first insertion layer DL1 disposed between the first dielectric film 181 and the crystalline reinforced dielectric film 185, and a second insertion layer DL2 disposed between the second dielectric film 182 and the third dielectric film 183. The first and second insertion layers DL1 and DL2 may include or be formed of metals having different valences from each other.

Referring to FIG. 7B, a capacitor structure according to an example embodiment of the present disclosure may be understood as being similar to the capacitor structure CAP of the semiconductor device 100 illustrated in FIGS. 1 to 4, except that it has a different number of dielectric films 181 and 182 and one insertion layer DL1′. Furthermore, the components of an example embodiment of the present disclosure may be understood by referring to the description of the capacitor structure CAP and the dielectric layer 180 of the semiconductor device 100 illustrated in FIGS. 1 to 4, unless there is a specific contrary explanation thereof.

Unlike the previous example embodiment, a dielectric layer 180B employed in an example embodiment of the present disclosure may include the crystalline reinforced dielectric film 185, the first dielectric film 181, and the second dielectric film 182. The crystalline reinforced dielectric film 185 may be disposed on a bottom of the plurality of dielectric films and may act as a seed layer for improving the crystallinity of the first dielectric film to be subsequent grown. In some example embodiments, the crystalline reinforced dielectric film 185 may include or be formed of rutile or anatase TiO₂, and the first dielectric film 181 formed thereon may include zirconium oxide having a tetragonal crystal structure. Furthermore, the second dielectric film 182 may include or be formed of hafnium oxide, and additionally improve the crystallinity thereof by the first dielectric film 181.

The dielectric layer 180B may include an insertion layer DL1′ between the first and second dielectric layers 181 and 182. Unlike the previous example embodiment, the insertion layer DL1′ adopted in an example embodiment of the present disclosure may include or be formed of two or more metals having different valences from each other. For example, the insertion layer DL1′ may include or be formed of an oxide or a nitride (or two kinds of oxides or nitrides containing each metal) containing a trivalent metal (Al) and a pentavalent metal (Nb).

Referring to FIG. 7C, a capacitor structure according to an example embodiment of the present disclosure may be understood as being similar to the semiconductor device CAP illustrated in FIGS. 1 to 4, except that the capacitor structure has a different number of dielectric films 181, 182 and 183, has different positions and configurations of the first and second insertion layers DL1′ and DL2, and introduces two crystalline reinforced dielectric films 185A and 185B. Furthermore, the components of an example embodiment of the present disclosure may be understood by referring to the description of the capacitor structure CAP and the dielectric layer 180 of the semiconductor device 100 illustrated in FIGS. 1 to 4, unless there is a specific contrary explanation thereof.

Unlike the previous example embodiment, a dielectric layer 180C employed in an example embodiment of the present disclosure may include the first crystalline reinforced dielectric film 185A, the first dielectric film 181, the second dielectric film 182, the second crystalline reinforced dielectric film 185B, and the third dielectric film 183. Similarly to the example embodiment of FIG. 7B, the first crystalline reinforced dielectric film 185A may be disposed at the bottom of the plurality of dielectric films and may serve as a seed layer for improving the crystallinity of the first dielectric film 181 to be subsequent grown. In some example embodiments, the first crystalline reinforced dielectric film 185A may include or be formed of rutile or anatase TiO₂, and the first dielectric film 181 may include zirconium oxide having a tetragonal crystal structure. Furthermore, the second dielectric film 182 may include or be formed of hafnium oxide, and additionally improve the crystallinity thereof by the first dielectric film 181.

Furthermore, the second crystalline reinforced dielectric film 185B may improve the crystallinity of the adjacent second and third dielectric layers 182 and 183. The second crystalline reinforced dielectric film 185B may include or be formed of rutile or anatase TiO₂, and at least the third dielectric film 183 may include or be formed of zirconium oxide having a tetragonal crystal structure.

The dielectric layer 180C according to an example embodiment of the present disclosure may include a first insertion layer DL1′ between the first and second dielectric layers 181 and 182, and a second insertion layer DL2 between the third dielectric film 183 and the second interface layer IL2. Unlike the previous example embodiment, the insertion layer DL1′ adopted in an example embodiment of the present disclosure may include two or more metals having different valences. For example, the first insertion layer DL1′ may include or be formed of an oxide or a nitride containing a trivalent metal (e.g., Al) and an oxide or a nitride containing a pentavalent metal (e.g., Nb), and the second insertion layer DL2 may include or be formed of an oxide or a nitride containing a different metal (e.g., Y) from the metal of the first insertion layer DL1′.

Referring to FIG. 7D, a capacitor structure according to an example embodiment of the present disclosure may be understood as being similar to the capacitor structure CAP of the semiconductor device 100 illustrated in FIGS. 1 to 4, except that it includes one dielectric film 181 and one crystalline reinforced dielectric film 185 and does not include an insertion layer. Furthermore, the components of an example embodiment of the present disclosure may be understood by referring to the description of the capacitor structure CAP and the dielectric layer 180 of the semiconductor device 100 illustrated in FIGS. 1 to 4, unless there is a specific contrary explanation thereof.

Unlike the previous example embodiment, a dielectric layer 180D employed in the present embodiment may include the crystalline reinforced dielectric film 185 and one first dielectric film 181. The crystalline reinforced dielectric film 185 may be disposed beneath the first dielectric film 181 and may serve as a seed layer for improving the crystallinity of the first dielectric film 181 to be subsequent grown. In some example embodiments, the crystalline reinforced dielectric film 185 may include or be formed of rutile or anatase TiO₂, and the first dielectric film 181 formed thereon may include or be formed of zirconium oxide having a tetragonal crystal structure. Alternatively, the first dielectric film 181 may be formed first, and the crystalline reinforced dielectric film 185 may be formed on the first dielectric film 181. Even in the instant case, the crystallinity of the first dielectric film 181 may be improved by the crystalline reinforced dielectric film 185 in a subsequent heat treatment process.

In the top plan view of the semiconductor device 100 illustrated in FIG. 1, a portion of each side surface of four lower electrodes 170 (or first electrodes) of an opening of the at least one support layer 171 or 172 may be exposed, but the example embodiment is not limited thereto. FIG. 8 is a top plan view illustrating a semiconductor device according to an example embodiment of the present disclosure.

Referring to FIG. 8, one through-hole pattern may be disposed between three adjacent lower electrodes 170 (or first electrodes). However, the through-hole pattern is not limited thereto, and for example, one through-hole pattern may be disposed between six adjacent lower electrodes 170.

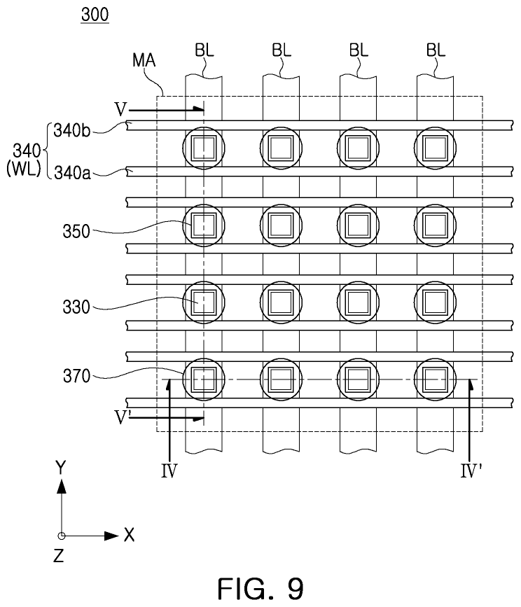

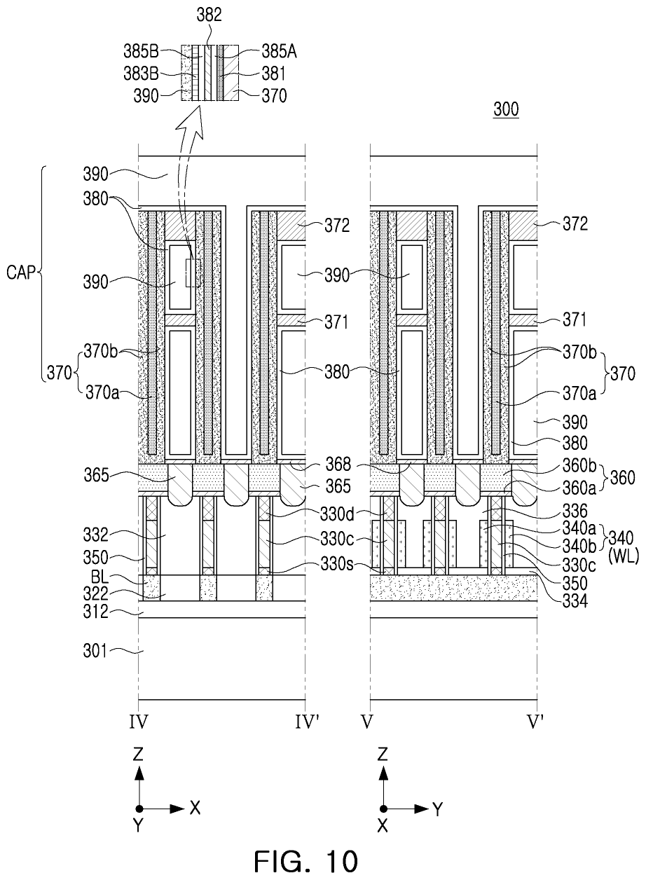

FIG. 9 is a top plan view illustrating a semiconductor device according to an example embodiment of the present disclosure, and FIG. 10 is cross-sectional views of the semiconductor device of FIG. 9 taken along line IV-IV′ and line V-V′ according to example embodiments.

Referring to FIGS. 9 and 10, a semiconductor device 300 according to an example embodiment of the present disclosure may include a substrate 301, a plurality of bit lines BL disposed in a memory cell array MA on the substrate 301, vertical structures 300 (channel regions 330c, lower source/drain regions 330s, and upper source/drain regions 330d), word lines WLs connected to cell gate electrodes 340 (340a and 340b), and cell gate dielectrics 350. The substrate 301 may be a semiconductor substrate, as illustrated in FIGS. 1 and 2.

The channel regions 330c, the lower source/drain regions 330s, the upper source/drain regions 330d, and the cell gate electrodes 340 may constitute vertical channel transistors. Here, the vertical channel transistors may be referred to as cell transistors. The vertical channel transistor may refer to a structure in which a channel length of each of the channel regions 330c extends in a vertical direction (Z-direction) from the substrate 301.

A lower insulating layer 312 may be disposed on the substrate 301. On the lower insulating layer 312, the plurality of bit lines BL may be spaced apart from each other in the first direction (X-direction) and may extend in the second direction (Y-direction). A plurality of first lower insulating patterns 322 filling a space between the plurality of bit lines BL may be formed on the lower insulating layer 312. The plurality of first lower insulation patterns 322 may extend in the second direction (Y-direction), and an upper surface of the plurality of first lower insulation patterns 322 may be disposed on the same level as an upper surface of the plurality of bit lines BL.

In some example embodiments, each of the plurality of bit lines BL may include doped polysilicon, a metal, conductive metal nitride, conductive metal silicide, conductive metal oxide, or combinations thereof. For example, each of the bit lines BL may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or combinations thereof, but the present disclosure is not limited thereto. Each of the bit lines BL may include a single layer or multiple layers of the above-described materials. In some example embodiments, each of the bit lines BL may include a two-dimensional semiconductor material, and for example, the two-dimensional semiconductor material may include graphene, a carbon nanotube, or combinations thereof.

The channel regions 330c may be arranged in a matrix form in which they are spaced apart from each other in the first direction and the second direction on the bit lines BL. The lower source/drain regions 330s, the channel regions 330c, and the upper source/drain regions 330d may be sequentially stacked. In some example embodiments, any one channel region 330c and the lower and upper source/drain regions 330s and 330d disposed below/above any one channel region 330c may have a first width in the first direction (X-direction) and a first height in the vertical direction (Z-direction), and the first height may be greater than the first width. For example, the first height may be about 2 to 10 times greater than the first width, but the present disclosure is not limited thereto.

In some example embodiments, each of the channel regions 330c may include an oxide semiconductor, for example, the oxide semiconductor includes InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, and combinations thereof. Each of the channel regions 330c may include a single layer or multiple layers of the oxide semiconductor. For example, each of the channel regions 330c may have bandgap energy greater than a bandgap energy of silicon. For example, each of the channel regions 330c may be polycrystalline or amorphous, but the present disclosure is not limited thereto.

In some example embodiments, each of the channel regions 330c may include a two-dimensional semiconductor material, for example, the two-dimensional semiconductor material may include graphene, carbon nanotubes, or combinations thereof. In some example embodiments, each of the channel regions 330c may include a semiconductor material such as silicon.

Hereinafter, one channel region 330c and one cell gate electrode 340 will be mainly described, but a plurality of channel regions 330c and a plurality of cell gate electrodes 340 may be understood.

The cell gate electrode 340 may extend in the first direction (X-direction) on opposite sidewalls of the channel region 330c. The cell gate electrode 340 may include a first sub-gate electrode 340a facing a first sidewall of the channel region 330c and a second sub-gate electrode 340b facing a second sidewall opposite to the first sidewall of the channel region 330c. As one channel region 330c is disposed between the first sub-gate electrode 340a and the second sub-gate electrode 340b, the semiconductor device 300 may have a dual-gate transistor structure. However, the technical concept of the present disclosure is not limited thereto, and a single-gate transistor structure may be implemented by omitting the second sub-gate electrode 340b and forming only the first sub-gate electrode 340a facing the first sidewall of the channel region 330c.

Each of the first and second sub-gate electrodes 340a and 340b may include doped polysilicon, a metal, conductive metal nitride, conductive metal silicide, conductive metal oxide, or combinations thereof. For example, the cell gate electrode 340 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, or combinations thereof.

A cell gate dielectric 350 may surround the sidewall of the channel region 330c and may be interposed between the channel region 330c and the cell gate electrode 340. For example, an entire sidewall of the channel region 330c may be surrounded by the cell gate dielectric 350, and a portion of the sidewall of the cell gate electrode 340 may be in contact with the cell gate dielectric 350. In other example embodiments, the cell gate dielectric 350 may extend in an extending direction of the cell gate electrode 340, that is, in the first direction (X-direction), and among the sidewalls of the channel region 330c, only two sidewalls facing the cell gate electrode 340 may be in contact with the cell gate dielectric 350.

In some example embodiments, the cell gate dielectric 350 may be formed of a silicon oxide film, a silicon oxynitride film, a high-k dielectric film with a higher dielectric constant than the silicon oxide film, or combinations thereof. The high-k dielectric film may be formed of metal oxide or metal oxynitride. For example, the high-k dielectric film available as the cell gate dielectric 350 may be formed of HfO₂, HfSiO, HfSiON, HfTaO, HfTiO, HfZrO, ZrO₂, Al₂O₃, or combinations thereof, but the present disclosure is not limited thereto.

A plurality of second lower insulation patterns 332 may be disposed on the plurality of first lower insulation patterns 322. The second lower insulation patterns 332 may extend in the second direction, and the channel region 330c may be disposed between two adjacent second lower insulation patterns 332 among the plurality of second lower insulation patterns 332. Between the two adjacent second lower insulation patterns 332, a first buried layer 334 and a second buried layer 336 may be disposed in a space between two adjacent channel regions 330c. The first buried layer 334 may be disposed on a bottom of a space between the two adjacent channel regions 330c, and the second buried layer 336 may be formed on the first buried layer 334 to fill the remainder of the space between the two adjacent channel regions 330c. An upper surface of the second buried layer 336 may be disposed on the same level as an upper surface of the upper source/drain region 330d, and the second buried layer 336 may cover an upper surface of the cell gate electrode 340. Alternatively, the plurality of second lower insulation patterns 332 may be formed of a material layer continuous with the plurality of first lower insulation patterns 322, or the second buried layer 336 may be formed of a material layer continuous with the first buried layer 334.

Contact structures 360 may be electrically connected to and on the upper source/drain regions 330d. Insulating isolation patterns 365 may be disposed between the contact structures 360. Each of the contact structures 360 may include a barrier layer 360a and a metal layer 360b on the barrier layer 360a. The contact structures 360 and the insulating isolation patterns 365 may be covered by an etch stop layer 368.

The semiconductor device 300 according to an example embodiment of the present disclosure may further include a capacitor structure CAP and at least one support layer 371 or 372. The capacitor structure CAP may be a capacitor of a memory cell storing information in a DRAM device. The capacitor structure CAP may be referred to as an information storage structure. The capacitor structure CAP may include first electrodes 370, second electrodes 390 on the first electrodes 370, and a dielectric layer 380 between the first electrodes 370 and the second electrodes 390.

In example embodiments, additional three or more support layers spaced apart from each other in a direction (Z direction) may be disposed between the dielectric layer 380 and the etch stop layer 368. For example, the additional three or more support layers may support the first electrodes 370 between adjacent first electrodes 370.

The dielectric layer 380 adopted in an example embodiment of the present disclosure may include a first dielectric film 381, a first crystalline reinforced dielectric film 385A, a second dielectric film 382, a second crystalline reinforced dielectric film 385B, and a third dielectric film 383B. Each of the first and second crystalline reinforced dielectric films 385A and 385B may include or be formed of rutile or anatase TiO₂, and each of the first and third dielectric layers 381 and 383B may include or be formed of zirconium oxide having a tetragonal crystal structure. The first and third dielectric layers 381 and 383B may have improved crystallinity by the first and second crystalline reinforced dielectric films 385A and 385B. Furthermore, because each of the first and second crystalline reinforced dielectric films 385A and 385B have a high dielectric constant, they may guarantee high electrostatic capacity as an alternative high-k dielectric film. Furthermore, the second dielectric film 382 may include or be formed of hafnium oxide, and the second dielectric film 382 may also have improved crystallinity by the first and second crystalline reinforced dielectric films 385A and 385B. The dielectric layer described above may be replaced with various other multilayer dielectric structures (see FIG. 4 and FIGS. 7A to 7D) described above.

The first electrodes 370 may include first sub-electrodes 370a and second sub-electrodes 370b on the first sub-electrodes 370a. The first electrodes 370 may penetrate through the etch stop layer 368 and may be in contact with and electrically connected to the contact structures 360, penetrate through the etch stop layer 368, and extend upwardly. Each of the first electrodes 370 may have a columnar shape, but example embodiments are not limited thereto. For example, each of the first electrodes 370 may have a cylinder shape. The support layers 371 and 372 may include a lower support layer 371 and an upper support layer 372 disposed on different levels. The upper support layer 372 may be in contact with upper regions of the first electrodes 370 and may prevent the first electrodes 370 from collapsing, and the lower support layer 371 may be in contact with the first electrodes 370 on a lower level than the upper support layer 372 and may prevent deformation such as warpage of the first electrodes 370. Each of the lower and upper support layers 371 and 372 may include an insulating material such as silicon nitride. In the capacitor structure CAP, the dielectric layer 380 may be disposed along the surfaces of the first electrodes 370 and the lower and upper support layers 371 and 372 in contact with the first electrodes 370.

The present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

What is claimed is:

1. A semiconductor device comprising:
a substrate;
a first electrode disposed above the substrate;
a multilayer dielectric structure configured to cover the first electrode; and
a second electrode configured to cover the multilayer dielectric structure,
wherein the multilayer dielectric structure includes a plurality of dielectric films,
wherein a first dielectric film of the plurality of dielectric films includes crystalline TiO₂ or crystalline SrTiO₃, and
wherein a second dielectric film of the plurality of dielectric films is in contact with the first dielectric film and includes a high-k dielectric film having a tetragonal crystal structure.

2. The semiconductor device of claim 1, wherein the high-k dielectric film includes hafnium oxide or zirconium oxide.

3. The semiconductor device of claim 1, wherein the high-k dielectric film includes a first high-k dielectric film and a second high-k dielectric film formed of different materials, and
wherein the first high-k dielectric film is in contact with the first dielectric film.

4. The semiconductor device of claim 1, wherein the crystalline TiO₂ has a crystal structure of rutile, anatase, or brucite.

5. The semiconductor device of claim 1, wherein the crystalline SrTiO₃ has a perovskite crystal structure.

6. The semiconductor device of claim 1, wherein the first dielectric film has a dielectric constant of 40 or more.

7. The semiconductor device of claim 1, wherein the multilayer dielectric structure has a thickness of 100 Å or less.

8. The semiconductor device of claim 7, wherein the first dielectric film has a thickness of 10 Å to 30 Å.

9. The semiconductor device of claim 7, wherein the high-k dielectric film has a thickness of 5 Å to 20 Å.

10. The semiconductor device of claim 1, wherein the first dielectric film includes crystalline TiO₂, and the high-k dielectric film includes tetragonal ZrO₂.

11. The semiconductor device of claim 1, wherein the multilayer dielectric structure further includes an insertion layer disposed between adjacent dielectric films among the plurality of dielectric films, and
wherein the insertion layer includes an oxide or a nitride containing trivalent or pentavalent metal.

12. The semiconductor device of claim 11, wherein the insertion layer includes an oxide or a nitride containing a metal selected from the group consisting of Al, Y, La, B, In, V, Ta, and Nb.

13. The semiconductor device of claim 11, wherein the insertion layer has a thickness of 0.05 to 5 Å.

14. A semiconductor device comprising:
a substrate;
a plurality of first electrodes disposed on the substrate;
a multilayer dielectric structure configured to cover the plurality of first electrodes; and
a second electrode configured to cover the multilayer dielectric structure,
wherein the multilayer dielectric structure includes a plurality of dielectric films,
wherein the plurality of dielectric films include a first dielectric film and a second dielectric film formed of different materials, and a crystalline reinforced dielectric film having at least one surface in contact with the first dielectric film, and
wherein the first dielectric film includes hafnium oxide (HfO₂) or zirconium oxide (ZrO₂), and the crystalline reinforced dielectric film includes crystalline TiO₂ or crystalline SrTiO₃.

15. The semiconductor device of claim 14, wherein the first dielectric film includes a tetragonal zirconium oxide, and the crystalline reinforced dielectric film includes crystalline TiO₂.

16. The semiconductor device of claim 15, wherein the second dielectric film includes a material selected from the group consisting of hafnium oxide, aluminum oxide, yttrium oxide, scandium oxide, and lanthanum oxide.

17. The semiconductor device of claim 14, wherein the multilayer dielectric structure includes:
a first insertion layer disposed between adjacent dielectric films among the plurality of dielectric films, and
a second insertion layer disposed between other adjacent dielectric films among the plurality of dielectric films, and
wherein each of the first and second insertion layers includes an oxide or a nitride containing a metal of different valence from each other.

18. The semiconductor device of claim 14, further comprising:
a first interface layer disposed between the plurality of first electrodes and the multilayer dielectric structure; and
a second interface layer disposed between the second electrode and the multilayer dielectric structure.

19. The semiconductor device of claim 18, wherein each of the first interface layer and the second interface layer includes an oxide or a nitride including at least one element selected from the group consisting of Ta, Sb, Mo, Co, Nb, Cu, Ni, V, and W.

20. A semiconductor device comprising:
a device isolation layer configured to define active regions on a substrate;
gate electrodes intersecting the active regions and extending into the device isolation layer;
first impurity regions and second impurity regions disposed within the active regions on opposite sides of the gate electrodes;
bit lines disposed at a higher level than the gate electrodes and connected to the first impurity regions;
conductive patterns disposed on side surfaces of the bit lines and connected to the second impurity regions;
a plurality of first electrodes extending vertically on the conductive patterns and connected to each of the conductive patterns;
at least one support layer spaced apart from an upper surface of the substrate in a vertical direction, extending in a direction parallel to the upper surface of the substrate, and contacting a side surface of each of adjacent first electrodes among the plurality of first electrodes;
a multilayer dielectric structure configured to cover the plurality of first electrodes and the support layer; and
a second electrode configured to cover the multilayer dielectric structure,
wherein the multilayer dielectric structure includes a first dielectric film and a second dielectric film formed of different materials, and a crystalline reinforced dielectric film having at least one surface in contact with the first dielectric film, and
wherein the first dielectric film includes hafnium oxide (HfO₂) or zirconium oxide (ZrO₂), and the crystalline reinforced dielectric film includes crystalline TiO₂ or crystalline SrTiO₃.
